(19) United States
(12) Patent Application Publication
(10) Pub. No.: US 2026/0305380 A1
(43) Pub. Date: Oct. 1, 2026

(54) DOUBLE SIDED MULTI CHIP FOR LEADED PACKAGE

(71) Applicant: Texas Instruments Incorporated, Dallas, TX (US)

(72) Inventors: Francis Glyde Cubi Medina, LA UNION (PH); Lila Iysobelle Espejo Lu, Baguio City (PH); Mia Katrina Alsaga Cayabyab, Baguio City (PH)

(21) Appl. No.: 19/089,353

(22) Filed: Mar. 25, 2025

(51) Int. Cl. H01L 23/495; H01L 21/48; H01L 21/56; H01L 23/00; H01L 23/31; H01L 23/538; H01L 25/065; H05K 1/18

(52) U.S. Cl. CPC H10W 70/429; H05K 1/181; H10W 70/041; H10W 70/048; H10W 70/611; H10W 70/65; H10W 90/00; H10W 72/07236; H10W 74/016; H10W 74/10; H10W 74/114; H10W 74/15; H10W 90/724; H10W 90/734

(57) ABSTRACT

An electronic device includes a substrate having opposite first and second sides, a first semiconductor die attached to the first side of the substrate, a second semiconductor die attached to the second side of the substrate, and a lead attached to the first side of the substrate and extending outward from a lateral side of the electronic device. A method of fabricating an electronic device includes attaching a substrate to a lead frame, attaching a first semiconductor die to a first side of the substrate, attaching a second semiconductor die to a second side of the substrate, and trimming and forming a lead of the lead frame.

### BACKGROUND

Modern electronic device manufacturing advances continue to provide higher circuit density and more components in semiconductor dies. However, conventional integrated circuit device types are limited by the number of dies that can fit in a package and are limited by the surface area of a single plane of a lead frame die attach pad. Conventional approaches can fit multiple large dies in a package through stacked or side-by-side arrangements on one side of a lead frame die attach pad with bond wires forming circuit interconnections but are limited by the die attach pad area and complexities associated with wire bonding.

### SUMMARY

In one aspect, an electronic device includes a substrate having opposite first and second sides, a first semiconductor die attached to the first side of the substrate, a second semiconductor die attached to the second side of the substrate, and a lead that is attached to the first side of the substrate and extends outward from a lateral side of the electronic device.

In another aspect, a system includes a circuit board having a conductive pad, and an electronic device that includes a substrate having opposite first and second sides, a first semiconductor die attached to the first side of the substrate, a second semiconductor die attached to the second side of the substrate, and a lead attached to the first side of the substrate and extending outward from a lateral side of the electronic device, the lead soldered to the conductive pad of the circuit board.

In a further aspect, a method of fabricating an electronic device includes attaching a substrate to a lead frame, attaching a first semiconductor die to a first side of the substrate, attaching a second semiconductor die to a second side of the substrate, and trimming and forming a lead of the lead frame.

### BRIEF DESCRIPTION OF THE DRAWINGS

FIG. 1 is a partial sectional side elevation view of a multi-chip dual or quad flat pack electronic device with top and bottom dies attached to a substrate using solder bump connections and having lead connections to a system circuit board.

FIG. 1A is a top plan view of a quad flat pack implementation of the electronic device of FIG. 1.

FIG. 1B is a top plan view of a dual flat pack implementation of the electronic device of FIG. 1.

FIG. 1C is a partial sectional side elevation view of another multi-chip dual or quad flat pack electronic device with top and bottom dies attached to a substrate using metal pillar terminal connections and having gullwing lead connections to a system circuit board.

FIG. 2 is a flow diagram of a method of fabricating an electronic device.

FIGS. 3-12 are partial sectional side elevation views of the electronic device of FIG. 1 undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, sides, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

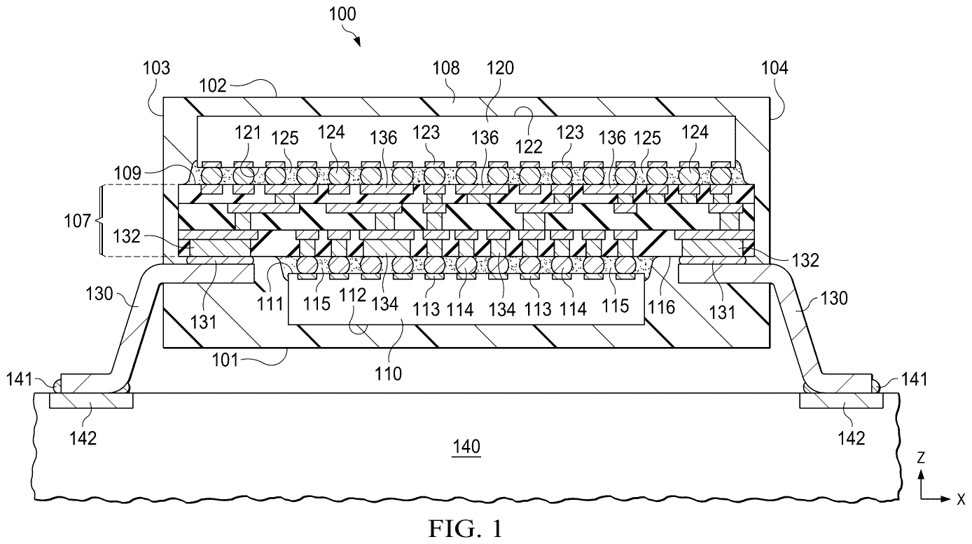

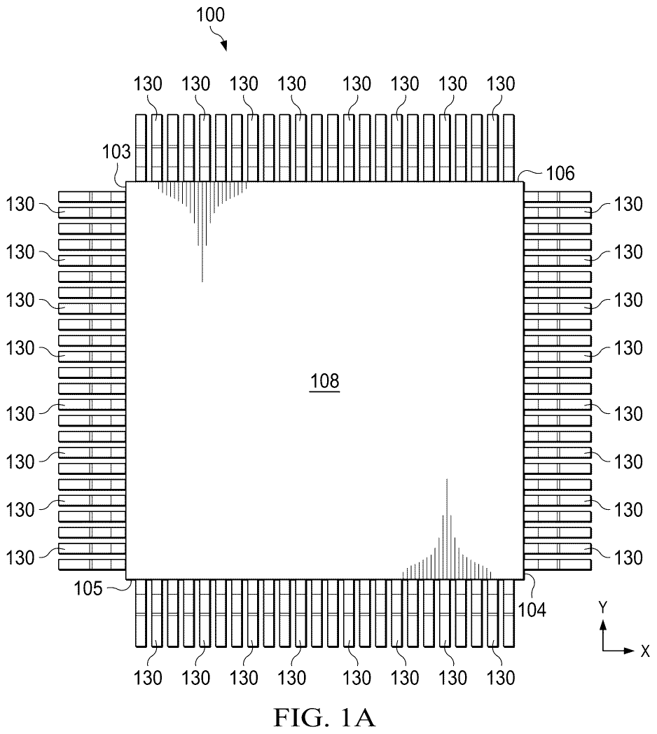

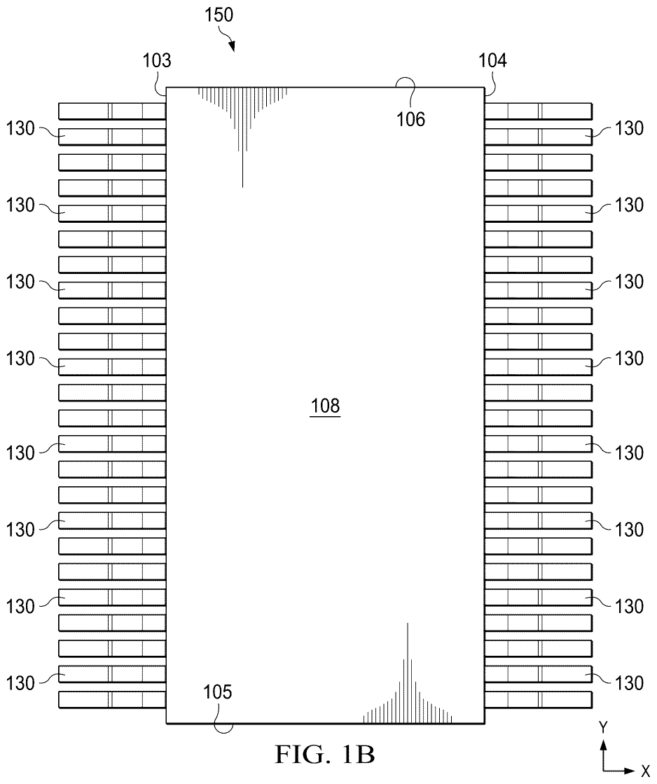

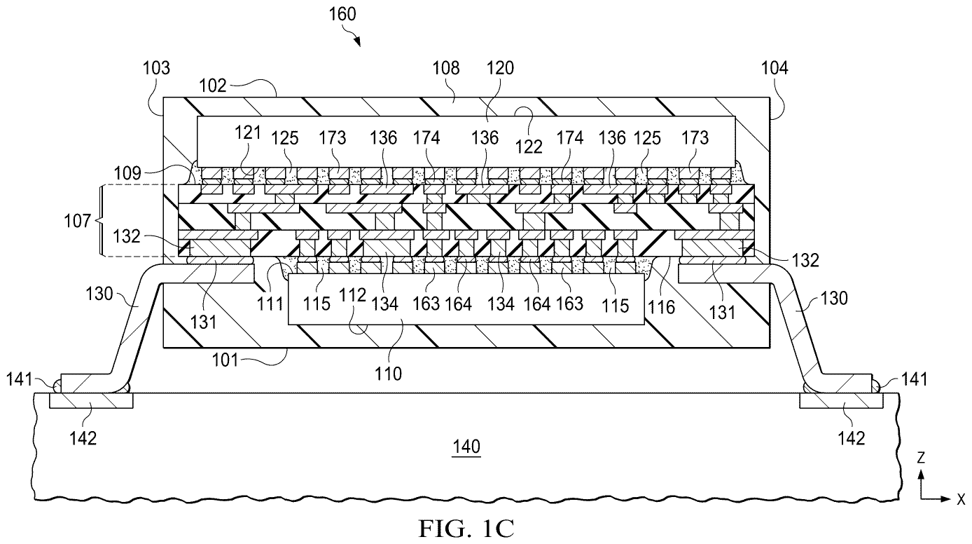

Referring to FIGS. 1-1C, FIGS. 1 and 1A show an example multi-chip quad flat pack implementation of an electronic device 100 using a multilevel package substrate 107 with attached leads 130, where the substrate 107 can be referred to as a leaded substrate 107. FIG. 1B shows an example multi-chip dual flat pack electronic device 150 with leads 130 on two laterally opposite sides 103 and 104. FIG. 1C shows another multi-chip dual or quad flat pack electronic device 160 with respective first and second semiconductor dies 110 and 120 attached to opposite sides of the substrate 107 using metal pillar terminal connections.

The electronic device 100 is shown in FIGS. 1 and 1A in an example position in a three-dimensional space with respective first, second, and third mutually orthogonal directions X, Y (FIG. 1A) and Z (FIG. 1). The electronic device 100 includes opposite first and second (e.g., bottom and top) sides 101 and 102 (FIG. 1) that are spaced apart from one another along the third direction Z. The electronic device 100 also includes lateral third and fourth sides 103 and 104 (FIGS. 1 and 1A) that are spaced apart from one another along the first direction X, and lateral fifth and sixth sides 105 and 106 (FIG. 1A) that are spaced apart from one another along the second direction Y.

The leaded substrate 107 has a first (e.g., lower or bottom) side 116 and an opposite second (e.g., upper or top) side 109. The electronic device 100 has a first semiconductor die 110 attached to the first side 116 of the substrate 107 and a second semiconductor die 120 attached to the second side 109 of the leaded substrate 107. In the illustrated example, the semiconductor dies 110 and 120 are attached by flip chip soldering operations using solder bump connections. In other examples, one or both of the semiconductor dies 110 and/or 120 can be attached by flip chip soldering using bump metal features (e.g., copper or other metal pillars or posts as shown in FIG. 1C) or other suitable attachment features and techniques, or combinations thereof. The example electronic devices 100, 150 and 160 incorporate the leaded substrate 107 and dies 110 and 120 attached to both sides of the substrate 107 using metal trace and via routings and exposed metal features on both sides to accommodate mounting of dies with bump metal pillars and/or solder bumps for high density applications.

The leaded substrate 107 has conductive metal features (e.g., copper, aluminum, etc.) that provide signal and power routing for the electronic device 100 including respective connections from one or both of the semiconductor dies 110 and/or 120 to the leads 130, as well as signal and/or power routing between the semiconductor dies 110 and 120. In one example, the substrate 107 is a multilevel package substrate that can also be referred to a routable lead frame (RLF) with prepreg or other suitable dielectric layers. The example substrate 107 is a three level stacked structure with dielectric layers and patterned conductive metal features including trace layer features and conductive metal via features. In other examples, any suitable number of two or more levels can be used with trace and/or via layer features such as a multilayer ETS or cored substrate.

The substrate 107 and the leads 130 provide mechanical and electrical connection of the electronic device 100 to conductive features 142 (e.g., metal pads) on the top side of a circuit board 140 using solder 141 as shown in FIG. 1. The substrate includes trace and via routings (e.g., conductive metal features) that provide desired electrical connections between the components of the device 100 and the leads 130. The substrate 107 has first conductive features 134 on the first side 116 (e.g., having approximately planar bottom surfaces exposed along the first side 116). In addition, the substrate 107 has second conductive features 136 on the second side 109 (e.g., having approximately planar bottom surfaces exposed along the second side 109), and third conductive features 132 on the first side 116 (e.g., having approximately planar bottom surfaces exposed along the first side 116).

The first semiconductor die 110 is attached to the first side 116 of the substrate 107, the second semiconductor die 120 is attached to the second side 109 of the substrate 107, the leads 130 are attached to the first side 116 of the substrate 107 and the individual leads 130 extend outward from respective lateral sides (e.g., 103, 104, 105, 106) of the electronic device 100. As shown in FIG. 1, the leads 130 in one example are electrically coupled by solder 131 to corresponding third conductive features 132 along a peripheral portion of the first side 116 of the substrate 107. In the illustrated example, the leads 130 are gullwing leads. In other examples, different lead types can be used having different shapes or forms (not shown). The leads 130 can be attached to either side 116 or 109 of the substrate 107. For example, the leads 130 can be attached (e.g., soldered) to corresponding conductive features (not shown) along the other side 109 of the substrate 107. In another implementation, the leads 130 can be attached to the respective third conductive features 132 using a conductive adhesive (not shown), or other suitable material that forms electrical and mechanical connection between the individual leads 130 and a respective one of the third conductive features 132 of the substrate 107.

The first semiconductor die 110 has opposite first and second sides 111 and 112 (e.g., respective top and bottom sides in the illustrated orientation of FIG. 1). In one example, the first side 111 is the die front side and the second side 112 is the die back side. The first conductive features 134 on the interior portion of the first side 116 of the substrate 107 are configured for flip-chip soldering of the first semiconductor die 110 to attach the first semiconductor die 110 to the first side 116 of the substrate 107. The first semiconductor die 110 has first terminals along the first side 111, which include conductive pads 113 (e.g., copper, aluminum, or other conductive metal) and solder bumps 114. The first terminals of the first semiconductor die 110 are electrically coupled to corresponding first conductive features 134 in the interior portion of the first side 116 of the substrate 107 (e.g., laterally inward from the soldered portions of the leads 130 and inward from the third conductive features 132). The electronic device 100 in the illustrated example includes a non-conductive underfill material 115 located between the first side 111 of the first semiconductor die 110 and the first side 116 of the substrate 107, and extends laterally between the adjacent terminals (e.g., conductive pads 113 and solder bumps 114) of the first semiconductor die 110.

The second semiconductor die 120 has opposite first and second sides 121 and 122 (e.g., respective bottom and top sides in the illustrated orientation of FIG. 1). In one example, the first side 121 is the die front side and the second side 122 is the die back side. The second conductive features 136 along the second side 109 of the substrate 107 are configured for flip-chip soldering of the second semiconductor die 120 to attach the second semiconductor die 120 to the second side 109 of the substrate 107. The second semiconductor die 120 has second terminals along the first side 121, which include conductive pads 123 (e.g., copper, aluminum, or other conductive metal) and solder bumps 124. The second terminals of the second semiconductor die 120 are electrically coupled to corresponding second conductive features 136 along the second side 109 of the substrate 107. The electronic device 100 in the illustrated example includes another non-conductive underfill material 125 located between the first side 121 of the second semiconductor die 120 and the second side 109 of the substrate 107. The underfill material 125 extends laterally between the adjacent terminals (e.g., conductive pads 123 and solder bumps 124) of the second semiconductor die 120.

As further shown in FIGS. 1 and 1A, the example electronic device 100 also includes a package structure 108 (e.g., a molded plastic or ceramic structure) that encloses a portion of the lead 130, the first semiconductor die 110, the second semiconductor die 120, and a portion of the substrate 107. In another implementation, a ceramic package structure (not shown) can be used, which can be separate from or integral with the substrate 107, and the electronic device can include a cavity within the ceramic package (e.g., above the second semiconductor die 120), with a lid structure that closes and seals the cavity (not shown). In another implementation, portions of either or both of the semiconductor dies 110, 120 can be exposed outside the package structure 108 (e.g., all or a portion of the top side 122 of the second semiconductor die 120 and/or the bottom side 112 of the first semiconductor die 110.

In another example, one or more additional electronic components (not shown) can be included in the electronic device 100, such as further semiconductor dies, passive or active surface mount components (e.g., resistors, capacitors, inductors, transformers, diodes, transistors, etc.) or combinations thereof, and which can be attached (e.g., soldered) to corresponding conductive features on the first and/or second side of the substrate 107.

As shown in FIG. 1A, one implementation of the electronic device 100 is a quad flat pack arrangement with leads 130 positioned along, and extending outwardly from, all four lateral sides 103-106 of the electronic device 100.

FIG. 1B shows another example electronic device 150, having internal components as described above in connection with the electronic device 100 of FIGS. 1 and 1A. The electronic device 150 in FIG. 1B is a dual flat pack structure having leads 130 that extend along, and outwardly from, two laterally opposite sides 103 and 104.

FIG. 1C shows another multi-chip (e.g., dual or quad flat pack) electronic device 160 with top and bottom dies 120, 110 attached to a substrate 107 using metal pillar terminal connections and having gullwing leads 130 connected to a system circuit board 140. The electronic device 160 in FIG. 1C includes similarly numbered structures and features as described above in connection with FIGS. 1 and 1A unless described differently herein. In this example, the first terminals of the first semiconductor die 110 include metal pillars 163 (e.g., copper or metal structures that may also be referred to as bumps or posts), which are electrically and mechanically coupled to the first conductive features 134 along the first side 116 of the substrate 107 by corresponding solder 164. Similarly, the second terminals of the second semiconductor die 120 in the example of FIG. 1C include metal pillars 173 electrically and mechanically coupled to the second conductive features 136 along the second side 109 of the substrate 107 by corresponding solder 174. In another possible implementation, one of the semiconductor dies 110, 120 includes solder bump terminals and the other semiconductor die uses metal pillars. In further implementations, one or both of the semiconductor dies 110, 120 can be attached to the corresponding side of the substrate 107 by other means (e.g., conductive or non-conductive die attach adhesive, not shown), and one or more electrical interconnections can be made by bond wires (not shown).

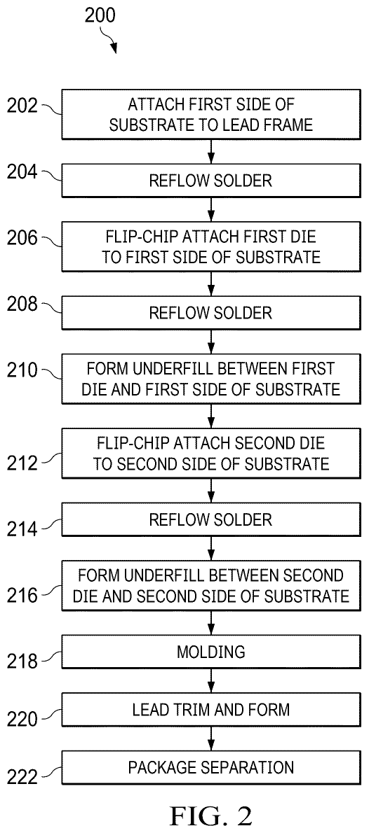

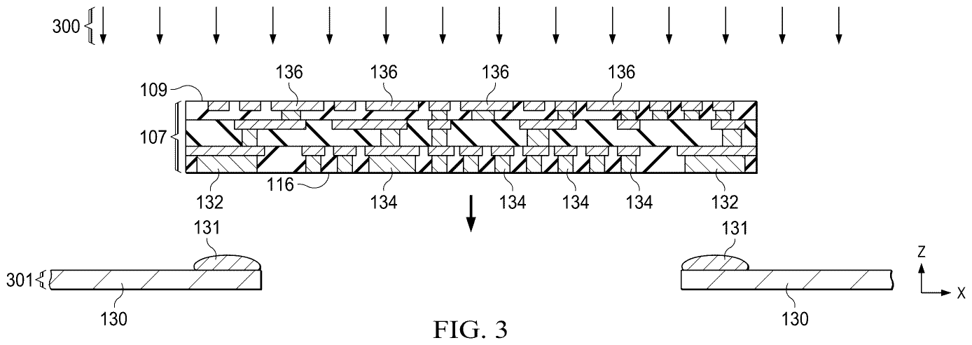

Referring now to FIGS. 2-10, FIG. 2 shows a method 200 of fabricating an electronic device, and FIGS. 3-10 illustrate the example electronic device 100 undergoing fabrication processing according to an implementation of the method 200. The method 200 begins with attachment of the substrate 107 to a lead frame at 202 and 204 in FIG. 2. The illustrated example includes a previously formed multilevel package substrate 107 that has been singulated or separated from a starting substrate panel array with multiple unit areas individually corresponding to an instance of the described multilevel package substrate 107. This example includes attachment of a separated substrate 107 in each unit area of a starting lead frame panel array having multiple unit areas individually corresponding to instances of a finished packaged electronic device 100 as described above. In another possible implementation, the substrate panel array can be attached to a starting lead frame panel array and various packaging processing can be performed prior to separation of individual unit areas of the substrate panel array and the lead frame panel array.

Referring also to FIGS. 2-12, FIG. 2 shows a method 200 of fabricating an electronic device, and FIGS. 3-12 illustrate the example electronic device 100 of FIGS. 1 and 1A undergoing fabrication processing according to an implementation of the method 200. The method 200 begins at 202 in FIG. 2 with attaching the substrate 107 to a lead frame. FIG. 3 shows one example, in which a starting lead frame 301 (e.g., copper or other suitable conductive material) is used having an array of rows and columns of unit areas, one of which is illustrated. The lead frame 301 in this example includes prospective lead features labeled 130 corresponding to the subsequently trimmed and formed leads 130 of the electronic device 100 being fabricated. In the illustrated example, the substrate attachment at 202 in FIG. 2 includes attaching an instance of the illustrated substrate 107 to an associated set of lead features 130 of the starting lead frame 301 in each unit area of the panel array structure. In this example, moreover, the substrate attachment at 202 includes electrically coupling a third conductive feature 132 on the first side 116 of the substrate 107 to the lead frame 301 in each unit area.

In one implementation, solder paste (e.g., or conductive adhesive) is formed on conductive features of a peripheral portion of a top side 116 of the substrate 107 on portions of the third conductive features 132 thereof. In the example of FIG. 3, a solder formation process is performed that forms the solder 131 on select portions of the top sides of prospective leads 130 of the lead frame 301. Any suitable solder paste, or adhesive formation processing and equipment can be used, such as silk screening, printing, etc. An attachment process 300 is performed in FIG. 3 that attaches the first side 116 of the substrate 107 to the lead frame 301. The process 300 attaches the first side 116 of the substrate 107 to prospective leads 130 of in the illustrated unit area of the lead frame 301. In one example, the process 300 includes similarly attaching further instances of the substrate 107 to prospective leads 130 in further unit areas (not shown) of the lead frame 301.

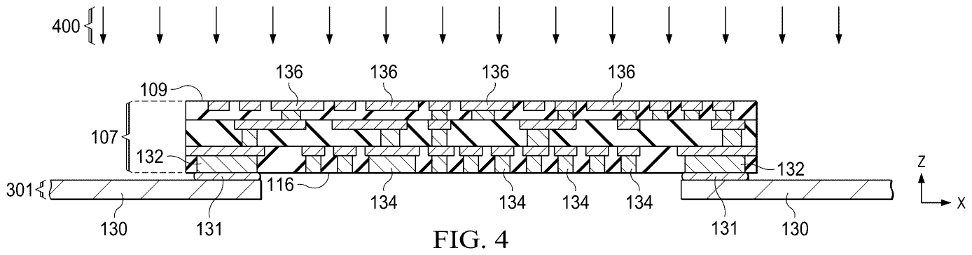

At 204 in FIG. 2, the illustrated example continues with reflowing the solder 131 to form solder connections between the prospective leads 130 of the lead frame 301 and the attached substrate 107. FIG. 4 shows one example, in which a thermal reflow process 400 is performed that reflows the solder 131 to form solder connections between the prospective leads 130 of the lead frame 301 and the respective third conductive features 132 along the first side 116 of the substrate 107 in each unit area of the lead frame panel array.

The illustrated example method 200 continues at 206-210 in FIG. 2 to attach the first semiconductor die 110 to the first side 116 of the lead frame 301 in each unit area using flip chip soldering equipment and techniques. In another example, the attachment at 206 can include dispensing die attach film or other adhesive (not shown) on a portion of the first side 116 of the substrate 107 and attachment of the first semiconductor die (e.g., using automated pick and place equipment, not shown) on the previously formed adhesive in the unit area of the lead frame 301.

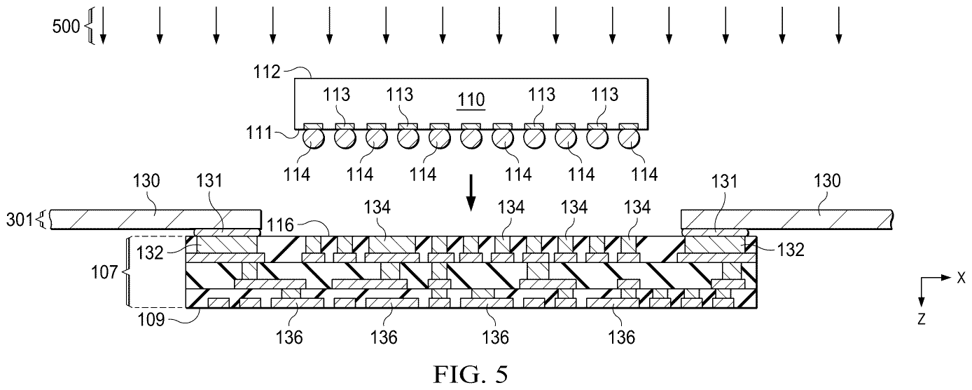

FIGS. 5-7 show one example, in which an instance of the first semiconductor die 110 is attached (e.g., at 206 and FIG. 2) to the interior portion of the first side 116 of the substrate 107, including electrically coupling the first terminals (e.g., conductive pads 113 and solder bumps 114) of the first semiconductor die 110 to respective first conductive features 134 on the first side 116 of the substrate 107 in each unit area. FIG. 5 shows one example, in which a die attachment process 500 is performed (e.g., using automated pick and place equipment, not shown) that attaches an instance of the first semiconductor die 110 to the interior portion of the first side 116 of the substrate 107. The illustrated example includes flip chip attachment of the first semiconductor die 110 to the first side 116 of the substrate 107, with the individual solder bumps 114 engaging the corresponding respective first conductive feature 134 of the substrate 107.

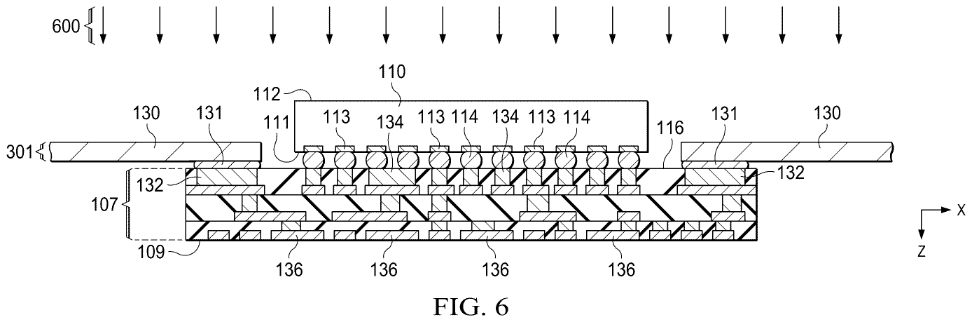

In one implementation, the electrical coupling of the first terminal 113, 114 of the first semiconductor die 110 to the first conductive feature 134 on the first side 116 of the substrate 107 includes reflowing the respective solder bumps 114 of the first semiconductor die 110 to solder a corresponding first conductive pad 113 of the first semiconductor die 110 to the respective first conductive feature 134 on the first side 116 of the substrate 107. The method 200 continues with reflow processing at 208 in FIG. 2 to form solder electrical connections of the first die terminals to the first conductive features 134 of the substrate 107. FIG. 6 shows one example, in which a thermal reflow process 600 is performed that forms or completes electrical connections between the conductive metal terminals 113, 114 of the first semiconductor die 110 and the corresponding first conductive features 134 of the substrate 107. In the illustrated example, the thermal process 600 reflows the solder bumps 114 to solder the conductive features 113 of the first semiconductor die 110 to the corresponding first conductive features 134 on the first side 116 of the substrate 107. In another example, where the first semiconductor die 110 was attached (e.g., at 206 in FIG. 2) using die attach adhesive, bond wires (not shown) can be formed to electrically connect conductive metal features (e.g., bond pads) of the first semiconductor die 110 to corresponding conductive features (not shown) of the substrate 107 and/or to connect bond pads of the first semiconductor die 110 to corresponding ones of the leads 130.

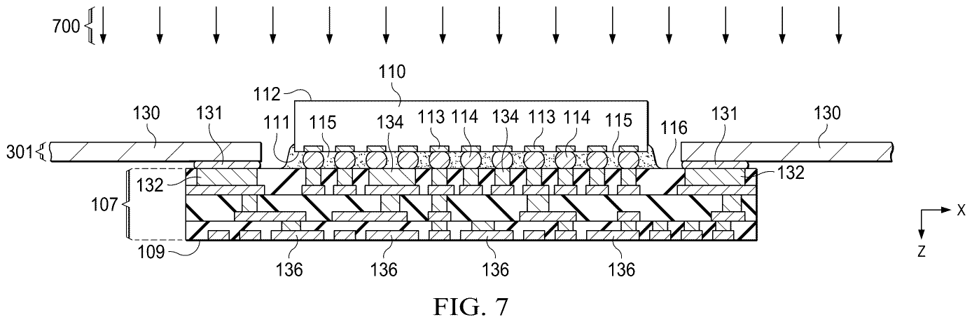

The method 200 in one example continues at 210 in FIG. 2 with optional underfill formation. FIG. 7 shows one example, in which an underfill process 700 is performed that forms the underfill material 115 between the bottom side of the first semiconductor die 110 and the top side 116 of the substrate 107 and laterally between the terminals 113 and solder bump connections 114. In another implementation, for example, where the first semiconductor die 110 is not flip chip soldered to the substrate 107, the underfill processing at 210 in FIG. 2 can be omitted.

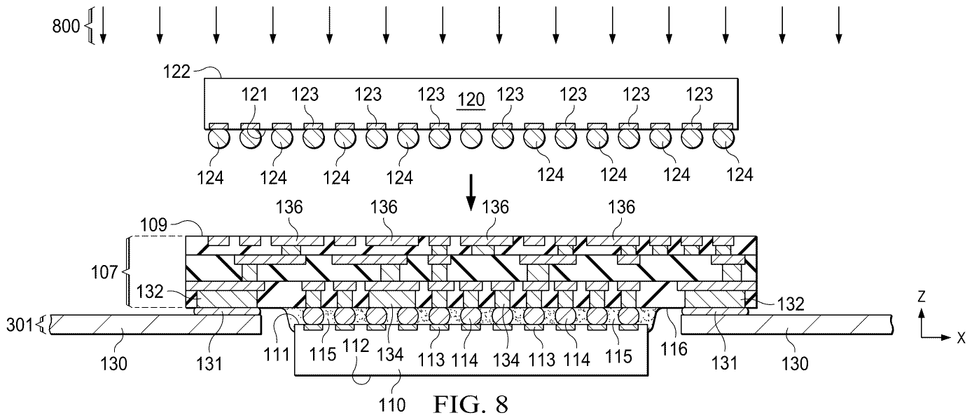

The method 200 continues at 212-216 in FIG. 2 with attachment of the second semiconductor die 120 to the second side 109 of the substrate 107, including electrically coupling the second terminals 123, 124 of the second semiconductor die 120 to the respective second conductive features 136 on the second side 109 of the substrate 107. FIGS. 8-10 show one example, with the lead frame panel array structure and inverted for the second die attach processing at 212-216 of FIG. 2. In this example, an instance of the second semiconductor die 120 is attached (e.g., at 212 and FIG. 2) to the second side 109 of the substrate 107, including electrically coupling the second terminals (e.g., conductive pads 123 and solder bumps 124) of the second semiconductor die 120 to respective second conductive features 136 on the second side 109 of the substrate 107 in each unit area.

FIG. 8 shows one example, in which a die attachment process 800 is performed (e.g., using automated pick and place equipment, not shown) that attaches an instance of the second semiconductor die 120 to the second side 109 of the substrate 107. The illustrated example includes flip chip attachment of the second semiconductor die 120 to the second side 109 of the substrate 107, with the individual solder bumps 124 engaging the corresponding respective second conductive features 136 of the substrate 107. In one implementation, the electrical coupling of the second terminals 123, 124 of the second semiconductor die 120 to the second conductive features 136 on the second side 109 of the substrate 107 includes reflowing the respective solder bumps 124 of the second semiconductor die 120 to solder a corresponding second conductive pad 123 of the second semiconductor die 120 to the respective second conductive feature 136 on the second side 109 of the substrate 107.

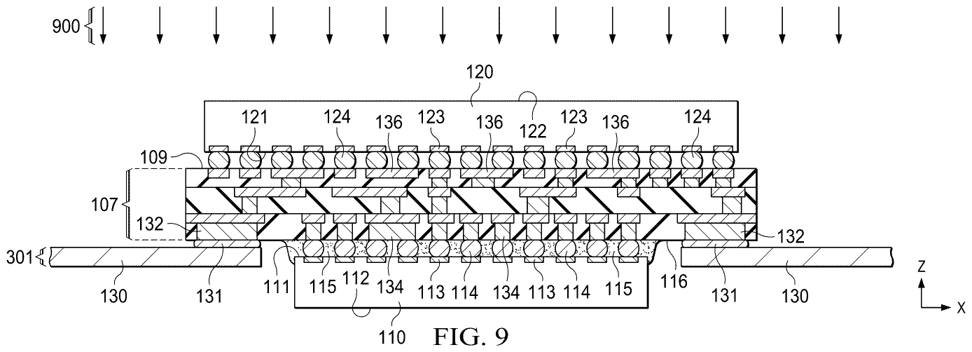

The method 200 continues with reflow processing at 214 in FIG. 2 to form solder electrical connections of the second die terminals to the second conductive features 136 of the substrate 107. FIG. 9 shows one example, in which a thermal reflow process 900 is performed that forms or completes electrical connections between the conductive metal terminals 123, 124 of the second semiconductor die 120 and the corresponding second conductive features 136 of the substrate 107. In the illustrated example, the thermal process 900 reflows the solder bumps 124 to solder the conductive features 123 of the second semiconductor die 120 to the corresponding second conductive features 136 on the second side 109 of the substrate 107. In another example, where the second semiconductor die 120 was attached (e.g., at 212 in FIG. 2) using die attach adhesive, bond wires (not shown) can be formed to electrically connect conductive metal features (e.g., bond pads) of the second semiconductor die 120 to corresponding conductive features (not shown) of the substrate 107 and/or to connect bond pads of the second semiconductor die 120 to corresponding ones of the leads 130.

During the second die attach reflow processing at 214, the previously soldered attachment of the first semiconductor die 110 to the first side 116 of the substrate 107 is aided by the presence of the first underfill material 115 to mitigate or prevent reflowing of the first solder bumps 114 during the reflow processing at 214 in FIG. 2. In addition, the choice between solder bumps (e.g., FIG. 1 above) and/or conductive pillars (e.g., FIG. 1C) and the associated solder reflow temperatures of the processing at 208 and 214 can be tailored to facilitate proper adhesion and solder connections of the first semiconductor die 110 while the solder connections of the second semiconductor die 110 are being formed.

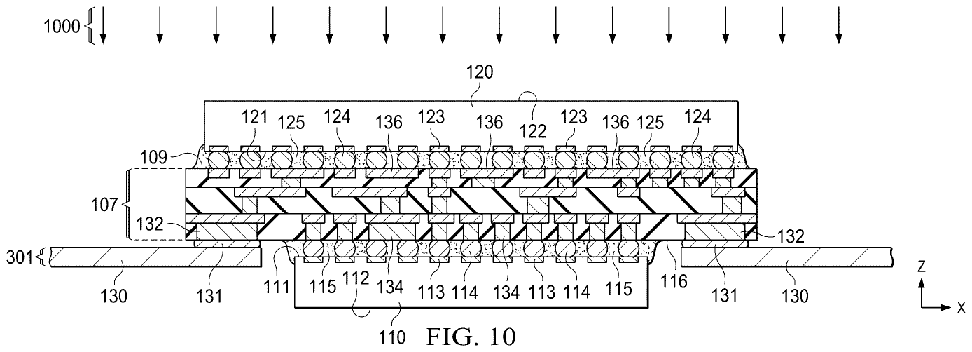

The method 200 in one example continues at 214 in FIG. 2 with optional underfill formation. FIG. 10 shows one example, in which an underfill process 1000 is performed that forms the underfill material 125 between the bottom side of the second semiconductor die 120 and the bottom side 109 of the substrate 107 and laterally between the terminals 123 and solder bump connections 124. In another implementation, for example, where the second semiconductor die 120 is not flip chip soldered to the substrate 107, the underfill processing at 214 in FIG. 2 can be omitted.

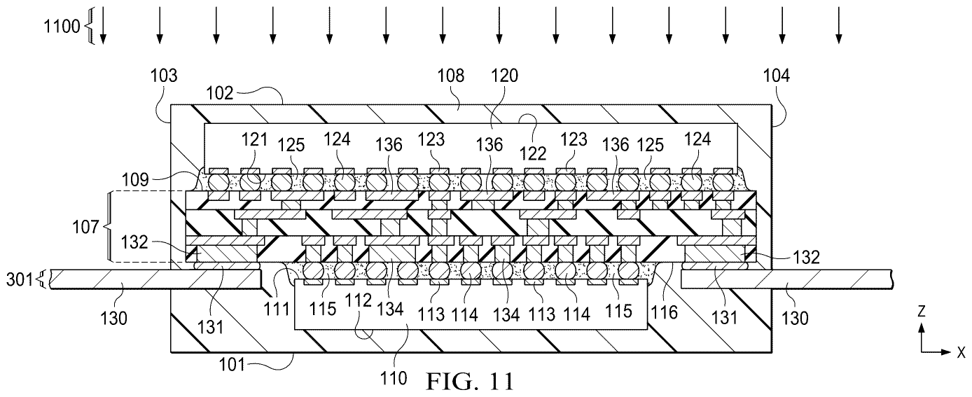

The method 200 continues at 218 in FIG. 2 with package molding. FIG. 11 shows one example, in which a molding process 1100 is performed using a mold (not shown). The process 1100 forms the molded package structure 108 to enclose the semiconductor dies 110 and 120, portions of the prospective leads 130 of the lead frame 301, and the substrate 107. In one implementation, a single mold cavity can be used to create a molded package structure 108 that extends across multiple unit areas of the lead frame 301. In other implementations, the mold includes individual mold cavities for each unit area or groups of fewer than all unit areas can be included within a shared mold cavity (not shown).

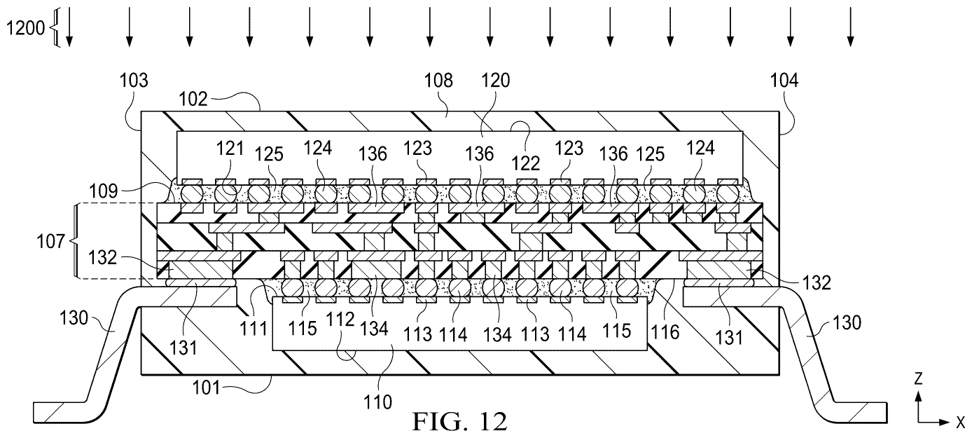

The method 200 continues at 220 in FIG. 2 with lead trimming and forming. FIG. 12 shows one example, in which a lead trimming and forming process 1200 is performed that trims and forms the prospective leads 130 in each unit area of the lead frame 301. The illustrated example process 1200 trims exposed portions of the lead frame 301 to separate the leads 130 of adjacent unit areas and then forms the trimmed leads 130 into the gullwing shape illustrated in FIGS. 1-1C and 12. In other implementations, alternate forming operations can be used to form leads having different shapes (not shown).

In one implementation, the method 200 proceeds with package separation at 222 in FIG. 2 to separate individual packaged electronic devices 100 from the starting lead frame panel array structure 301. The package separation at 222 in one example includes laser or saw cutting along scribe streets between adjacent rows and columns of unit areas of the starting lead frame panel array structure, for example, to cut through tie bars and other temporary support structures (not shown) of the starting lead frame 301.

Described examples can help increase the computational power and circuit density of electronic devices 100, 150, 160 by increasing the size and/or the number of dies that can fit, and certain implementations can increase the packaged die area up to 2× total area occupied inside the semiconductor package 108 compared with conventional die stacking and/or side-by-side die arrangements for multichip modules and other packaged electronic devices. In addition, the illustrated examples advantageously improve electrical connections from the semiconductor dies 110, 120 to the external leads 130 due to more controlled routing on the substrate 107 compared with limitations and processing complexities associated with wire bonding. Moreover, the illustrated examples mitigate added costs associated with forming bond wires.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a substrate having opposite first and second sides;
a first semiconductor die attached to the first side of the substrate;
a second semiconductor die attached to the second side of the substrate; and
a lead attached to the first side of the substrate and extending outward from a lateral side of the electronic device.

2. The electronic device of claim 1, wherein:
the substrate has a first conductive feature on the first side, a second conductive feature on the second side, and a third conductive feature on the first side;
the first semiconductor die has a first terminal electrically coupled to the first conductive feature of the substrate;
the second semiconductor die has a second terminal electrically coupled to the second conductive feature of the substrate; and
the lead is electrically coupled to the third conductive feature of the substrate.

3. The electronic device of claim 2, wherein the first and second terminals include conductive pads coupled to solder bumps.

4. The electronic device of claim 2, wherein the first and second terminals include metal pillars.

5. The electronic device of claim 2, wherein the lead is soldered to the third conductive feature of the substrate.

6. The electronic device of claim 2, further comprising an underfill material between the first semiconductor die and the first side of the substrate.

7. The electronic device of claim 2, further comprising another underfill material between the second semiconductor die and the second side of the substrate.

8. The electronic device of claim 1, comprising instances of the lead extending outward from two opposite lateral sides of the electronic device.

9. The electronic device of claim 1, comprising instances of the lead extending outward from four lateral sides of the electronic device.

10. The electronic device of claim 1, further comprising a package structure that encloses a portion of the lead, the first semiconductor die, the second semiconductor die, and a portion of the substrate.

11. The electronic device of claim 1, wherein the lead is a gullwing lead.

12. The electronic device of claim 1, wherein the substrate has multiple levels.

13. A system, comprising:
a circuit board having a conductive pad; and
an electronic device, including:
a substrate having opposite first and second sides;
a first semiconductor die attached to the first side of the substrate;
a second semiconductor die attached to the second side of the substrate; and
a lead attached to the first side of the substrate and extending outward from a lateral side of the electronic device, the lead soldered to the conductive pad of the circuit board.

14. A method of fabricating an electronic device, the method comprising:
attaching a substrate to a lead frame;
attaching a first semiconductor die to a first side of the substrate;
attaching a second semiconductor die to a second side of the substrate; and
trimming and forming a lead of the lead frame.

15. The method of claim 14, wherein:
attaching the first semiconductor die to the first side of the substrate includes electrically coupling a first terminal of the first semiconductor die to a first conductive feature on the first side of the substrate;
attaching the second semiconductor die to the second side of the substrate includes electrically coupling a second terminal of the second semiconductor die to a second conductive feature on the second side of the substrate; and
attaching the substrate to the lead frame includes electrically coupling a third conductive feature on the first side of the substrate to the lead frame.

16. The method of claim 15, wherein:
electrically coupling the first terminal of the first semiconductor die to the first conductive feature on the first side of the substrate includes reflowing a solder bump of the first semiconductor die to solder a first conductive pad of the first semiconductor die to the first conductive feature on the first side of the substrate; and
electrically coupling the second terminal of the second semiconductor die to the second conductive feature on the second side of the substrate includes reflowing a solder bump of the second semiconductor die to solder a second conductive pad of the second semiconductor die to the second conductive feature on the second side of the substrate.

17. The method of claim 15, wherein:
electrically coupling the first terminal of the first semiconductor die to the first conductive feature on the first side of the substrate includes soldering a metal pillar of the first semiconductor die to the first conductive feature on the first side of the substrate; and
electrically coupling the second terminal of the second semiconductor die to the second conductive feature on the second side of the substrate includes soldering a metal pillar of the second semiconductor die to the second conductive feature on the second side of the substrate.

18. The method of claim 14, wherein attaching the substrate to the lead frame includes soldering a conductive feature on the first side of the substrate to the lead frame.

19. The method of claim 14, further comprising forming an underfill material between the first semiconductor die and the first side of the substrate.

20. The method of claim 14, further comprising forming an underfill material between the second semiconductor die and the second side of the substrate.
